(19) United States
(12) Patent Application Publication
(10) Pub. No.: US 2026/0245626 A1
(43) Pub. Date: Aug. 20, 2026

(54) FAST PROGRAM OF NON-VOLATILE MEMORY CELLS

(71) Applicant: Sillicon Storage Technology, Inc., San Jose, CA (US)

(72) Inventors: Hieu Van Tran, San Jose, CA (US); THUAN VU, San Jose, CA (US); ANH LY, San Jose, CA (US)

(21) Appl. No.: 19/207,290

(22) Filed: May 13, 2025

Related U.S. Application Data
(60) Provisional application No. 63/761,146, filed on Feb. 20, 2025.

(51) Int. Cl. G11C 16/10; G11C 16/04; G11C 16/24; G11C 16/30

(52) U.S. Cl. CPC G11C 16/102; G11C 16/0433; G11C 16/24; G11C 16/30

(57) ABSTRACT

A method of operating a semiconductor device by applying positive voltages to a select gate and to a source region wherein current flows from the source region, through a channel region and to a bit line to increase a voltage on the bit line, after which a drain program voltage is maintained on the bit line whereby electrons from the current through the channel region are injected onto the floating gate. A method can include applying positive voltages to the select gate and to the source region and electrically coupling a voltage source to the bit line to decrease a voltage on the bit line, after which a drain program voltage is maintained on the bit line whereby current flows from the source region, through the channel region and to the bit line, and electrons from the current through the channel region are injected onto the floating gate.

### RELATED APPLICATIONS

This application claims the benefit of U.S. Provisional Application No. 63/761,146, filed Feb. 20, 2025, and which is incorporated herein by reference.

### FIELD OF THE INVENTION

The present invention relates to non-volatile memory cells of semiconductor devices, and more particularly to an array configuration and method for faster programming operations.

### BACKGROUND OF THE INVENTION

Split-gate non-volatile memory semiconductor devices are well known in the art. See for example U.S. Pat. No. 7,868,375, which discloses a four-gate memory cell configuration, and which is incorporated herein by reference for all purposes. Specifically, FIG. 1 of the present disclosure illustrates a pair of split gate non-volatile memory cells 10 each with spaced apart source and drain regions 14/16 formed in a silicon semiconductor substrate 12. The source region 14 can be referred to as a source line SL (because it commonly is connected to other source regions for other non-volatile memory cells 10 in the same row or column), and the drain region 16 is commonly connected to a bit line. A channel region 18 of the substrate 12 extends between the source/drain regions 14/16. A floating gate 20 is disposed over (i.e., vertically over and laterally overlapping) and insulated from (and directly controls the conductivity of) a first portion of the channel region 18 (and partially over, and insulated from, the source region 14). A control gate 22 is disposed over, and insulated from, the floating gate 20. A select gate 24 (also referred to as a word line gate) is disposed over, and insulated from, and directly controls the conductivity of, a second portion of the channel region 18. An erase gate 26 is disposed over and insulated from the source region 14 and is laterally adjacent to the floating gate 20. The erase gate 26 can include a notch that faces an edge of the floating gate 20.

A plurality of such memory cells 10 can be arranged in rows and columns to form a memory cell array, as illustrated in FIG. 2. While FIG. 1 only shows a pair of memory cells 10 (sharing a common source region 14 and erase gate 26), the memory cell pairs can be placed end to end to form a column of memory cells 10 (where the memory cell pairs can share a common drain region 16). While only two such columns are shown in FIG. 2, there can be many such columns. Each column can include a bit line 16a electrically connecting together all the drain regions 16 in the column. Each row of memory cells 10 can include a control gate line 22a electrically connecting together all the control gates 22 in the row of memory cells 10. For example, all the control gates 22 in each row of memory cells 10 can be formed as a continuous line of conductive material, where a portion of the continuous line passing through any given memory cell 10 serves as its control gate 22. Each row of memory cells 10 can include a select gate line 24a electrically connecting together all the select gates 24 in the row of memory cells 10. For example, all the select gates 24 in each row of memory cells 10 can be formed as a continuous line of conductive material, where a portion of the continuous line passing through any given memory cell 10 serves as its select gate 24. Each row of memory cell pairs can include an erase gate line 26a electrically connecting together all the erase gates 26 in the row of memory cell pairs. For example, all the erase gates 26 in each row of memory cell pairs can be formed as a continuous line of conductive material, where a portion of the continuous line passing through any given memory cell pair serves as its erase gate 26. Finally, each row of memory cell pairs can include a source line 14a electrically connecting together all the source regions 14 in the row of memory cell pairs. For example, all the source regions 14 in each row of memory cell pairs can be formed as a continuous line of conductive diffusion in the substrate 12, where a portion of the continuous line passing through any given memory cell pair serves as its source region 14.

Various combinations of voltages are applied to the control gate 22, select gate 24, erase gate 26 and source and drain regions 14/16, to program the split gate non-volatile memory cell 10 (i.e., inject electrons onto the floating gate 20), to erase the split gate non-volatile memory cell 10 (i.e., remove electrons from the floating gate 20), and to read the split gate non-volatile memory cell 10 (i.e., measure or detect the conductivity of the channel region 18, by for example measuring or detecting a read current through the channel region 18, to determine the program state of the floating gate 20).

Split gate non-volatile memory cell 10 can be operated in a digital manner, where the split gate non-volatile memory cell 10 is set to one of only two possible states: a programmed state and an erased state. The split gate non-volatile memory cell 10 is erased by placing a high positive voltage on the erase gate 26, and optionally a negative voltage on the control gate 22, to induce tunneling of electrons from the floating gate 20 to the erase gate 26 (leaving the floating gate 20 in a more positively charged state—the erased state). Split gate non-volatile memory cell 10 can be programmed by placing positive voltages on the control gate 22, erase gate 26, select gate 24 and source region 14, and a current on drain region 16. Electrons will then flow along the channel region 18 from the drain region 16 toward the source region 14, with electrons becoming accelerated and heated whereby some of them are injected onto the floating gate 20 by hot-electron injection (leaving the floating gate 20 in a more negatively charged state—the programmed state).

Split gate non-volatile memory cell 10 can be read by placing positive voltages on the select gate 24 (turning on the portion of channel region 18 under the select gate 24 by making it conductive) and drain region 16 (and optionally on the erase gate 26 and the control gate 22), and sensing current flow through the channel region 18. If the floating gate 20 is positively charged (i.e. split gate non-volatile memory cell 10 is erased), the split gate non-volatile memory cell 10 will turn on because the both portions of the channel region 18 are conductive due to the lack of electrons on the floating gate 20, and current will flow from drain region 16 to source region 14 (i.e. the split gate non-volatile memory cell 10 is sensed to be in its erased “1” state based on sensed current flow). If the floating gate 20 is negatively charged (i.e. split gate non-volatile memory cell 10 is programmed), the portion of channel region 18 under the floating gate is turned off (low conductivity), thereby preventing appreciable current flow (i.e., the split gate non-volatile memory cell 10 is sensed to be in its programmed “0” state based on no, or minimal, current flow). Memory cells 10 are considered non-volatile because they maintain their program state even when power is not applied to the semiconductor device. Memory cells 10 can be referred to as split gate non-volatile memory cells because two different gates (floating gate 20 and select gate 24), respectively, directly control the conductivity of two different portions of the channel region 18.

Table 1 below provides non-limiting examples of the voltages that can be used to perform the read, erase and program operations on the memory cell 10 of FIG. 1. To assist the discussion below, the voltage on the drain 16 during a read operation may be referred to as the drain read voltage Vdr, the voltage on the drain 16 during an erase operation may be referred to as the drain erase voltage Vde, and the voltage on the drain 16 during a program operation may be referred to as the drain program voltage Vdp.

TABLE 1

| Operation | SG 24 | | Drain 16 | CG 22 | | EG 26 | | Source 14 | |
|---|---|---|---|---|---|---|---|---|---|
| Read | 1.0-2 | V | Vdr = 0.6-2 V | 0-2.6 | V | 0-2.6 | V | 0 | V |
| Erase | −0.5 V or 0 V | | Vde = 0 V | 0 V or −8 V | | 8-12 | V | 0 | V |
| Program | 1 | V | Vdp = ~0.3 V | 8-11 | V | 4.5-9 | V | 4.5-5 | V |
| | | | (1 uA) | | | | | | |

One technique to program the memory cells 10 is sequential programming, which involves applying the programming voltages as a series of pulses, with each pulse of programming voltages injecting more electrons onto the floating gate thus increasing the program state of the memory cell 10 with each pulse, until the desired program state (also referred to as the target program state) is achieved (i.e., until the target read current for the target program state is achieved). With sequential programming, there can be intervening read operations between the programming pulses to determine if the target program state has been achieved by the last applied programming pulse (in which case programming ceases) or has not been achieved (in which case programming continues with one or more programming pulses). For example, each target program state can be associated with a target read current Irtarget (i.e., the desired and therefore target current through the channel region 18 during a read operation that is associated with the target program state). The higher the program state (i.e., the more electrons on the floating gate), the lower the read current Ir. Therefore, read current Ir will drop after each programming pulse. Once a target read current Irtarget is reached (reflecting the desired or target program state), programming for that memory cell 10 ceases.

If the same set of program voltages are applied during each pulse in sequential programming, the programming amount drops pulse to pulse, because as the floating gate becomes more negatively charged with each pulse, fewer electrons are injected onto the floating gate if the parameters of the programming pulses (applied voltages, supplied current, duration) remain constant. Therefore, when a memory cell 10 is determined to have not reached its target program state after any given pulse, one or more of the programming parameters can be stepped up to a higher value in the next pulse, to compensate for the dropping pulse-to-pulse programming amount that would otherwise occur. For example, for the memory cell 10 of FIG. 1, programming parameters that can be stepped up from one programming pulse to the next programming pulse can include increases in one or more of the following: voltage applied to the control gate, voltage applied to the erase gate, voltage applied to the source region, current supplied to the drain region, and duration of the programming pulse.

Split gate non-volatile memory cell 10 can alternately be operated in an analog manner where the program state (i.e. the amount of charge, such as the number of electrons, on the floating gate 20) of the split gate-non-volatile memory cell 10 can be incrementally changed anywhere from a fully erased state (minimum number of electrons on the floating gate 20) to a fully programmed state (maximum number of electrons on the floating gate 20), or just a portion of this range. This means the split gate non-volatile memory cell 10 storage is analog, which allows for very precise and individual tuning of each split gate non-volatile memory cell 10 in an array of split gate non-volatile memory cells 10. Alternatively, the split gate non-volatile memory cell 10 could be operated as an MLC (multilevel cell) where it is configured to be programmed to one of many discrete values (such as 16 or 64 different values).

Split gate non-volatile memory cells with fewer gates are also known. For example, FIG. 3 illustrates known split gate non-volatile memory cells 10 that are the same as that of FIG. 1, except the control gates 22 are omitted. See for example U.S. Pat. No. 7,315,056, which is incorporated herein by reference for all purposes. Voltage coupling to the floating gate 20 provided by the control gate 22 of the split gate non-volatile memory cell 10 of FIG. 1 is provided instead by the erase gate 26 and source region 14 of the split gate non-volatile memory cell 10 in FIG. 3. FIG. 4 illustrates an example layout of an array of the split gate non-volatile memory cells 10 of FIG. 3. Table 2 below provides non-limiting examples of the voltages that can be used to perform the read, erase and program operations on the memory cell 10 of FIG. 3.

TABLE 2

| Operation | SG 24 | | Drain 16 | EG 26 | | Source 14 | |
|---|---|---|---|---|---|---|---|
| Read | 0.7-2.2 | V | Vdr = 0.6-2 V | 0-2.6 | V | 0 | V |
| Erase | −0.5 v or 0 V | | Vde = 0 V | 11.5 | V | 0 | V |
| Program | 1 | V | Vdp = ~0.3 V | 4.5-9 | V | 7-9 | V |
| | | | (2-3 uA) | | | | |

As another example, FIG. 5 illustrates known split gate non-volatile memory cells 10 that are similar to that of FIG. 1, except the control gates 22 and the erase gates 26 are omitted. See for example U.S. Pat. No. 5,029,130, which is incorporated herein by reference for all purposes. The erase voltage for the split gate non-volatile memory cell 10 of FIG. 5 is applied to the select gate 24, which has a first portion laterally adjacent the floating gate 20, and a second portion that extends up and over the floating gate 20. FIG. 6 illustrates an example layout of an array of the split gate non-volatile memory cells 10 of FIG. 5. Table 3 below provides non-limiting examples of the voltages that can be used to perform the read, erase and program operations on the memory cell 10 of FIG. 5.

TABLE 3

| | | | |
|---|---|---|---|
| Operation | SG 24 | Drain 16 | Source 14 |

| | | | | | |
|---|---|---|---|---|---|
| Read | 2-3 | V | Vdr = 0.6-2 V | 0 | V |
| Erase | 11-13 | V | Vde = 0 V | 0 | V |
| Program | 1-2 | V | Vdp = ~0.3 V | 9-10 | V |
| | | | (1-3 uA) | | |

As yet another example, FIG. 7 illustrates known split gate non-volatile memory cells 10 that are similar to that of FIG. 5, except a conductive block of material 28 is formed in contact with source region 14, to serve as an extended source line. See for example U.S. Pat. No. 6,855,980, which is incorporated herein by reference for all purposes. An example layout for an array of the split gate non-volatile memory cells 10 of FIG. 7 can be the same as that in FIG. 6.

The time needed to perform hot electron injection programming can be prolonged by the relatively significant capacitance of the bit lines 16a. Specifically, when the program voltages are applied to the respective lines to program a selected memory cell, the respective lines quickly achieve their target voltages. However, the bit lines 16a tend to achieve their target voltages more slowly than the other lines, thus delaying the beginning of memory cell programming. This time lag in achieving the desired programming voltage on the bit lines 16a can negatively impact device performance especially when considered cumulatively across an array of thousands or more memory cells. There is a need to reduce the time needed to achieve the desired voltage on the bit lines 16a during programming.

### BRIEF SUMMARY OF THE INVENTION

The aforementioned problems and needs are addressed by a method of operating a semiconductor device, wherein the semiconductor device comprises a source region and a drain region formed in a semiconductor substrate, with a channel region of the semiconductor substrate extending between the source region and the drain region, a floating gate disposed over and insulated from, for controlling a conductivity of, a first portion of the channel region, a select gate disposed over and insulated from, for controlling a conductivity of, a second portion of the channel region, a bit line electrically connected to the drain region, and a current source. The method comprises applying a first positive voltage to the select gate, applying a second positive voltage to the source region, wherein current flows from the source region, through the channel region and to the bit line to increase a voltage on the bit line, and after the increase of the voltage on the bit line, maintaining a drain program voltage on the bit line whereby electrons from the current through the channel region are injected onto the floating gate.

A semiconductor device comprises a source region and a drain region formed in a semiconductor substrate, with a channel region of the semiconductor substrate extending between the source region and the drain region, a floating gate disposed over and insulated from, for controlling a conductivity of, a first portion of the channel region, a select gate disposed over and insulated from, for controlling a conductivity of, a second portion of the channel region, a bit line electrically connected to the drain region, a current source, a switch electrically connected between the bit line and the current source, wherein the switch has a closed state that electrically couples the bit line to the current source through the switch, and wherein the switch has an open state that electrically isolates the bit line from the current source, and control circuitry to place the switch in the closed state, and apply a first positive voltage to the select gate and a second positive voltage to the source region, to enable current from the source region, through the channel region and to the bit line to increase a voltage on the bit line.

A method of operating a semiconductor device, wherein the semiconductor device comprises a source region and a drain region formed in a semiconductor substrate, with a channel region of the semiconductor substrate extending between the source region and the drain region, a floating gate disposed over and insulated from, for controlling a conductivity of, a first portion of the channel region, a select gate disposed over and insulated from, for controlling a conductivity of, a second portion of the channel region, a bit line electrically connected to the drain region, a current source, and discharge circuitry comprising a voltage source. The method comprises applying a first positive voltage to the select gate, applying a second positive voltage to the source region, electrically coupling the voltage source to the bit line to decrease a voltage on the bit line, and after the decrease of the voltage on the bit line, maintaining a drain program voltage on the bit line whereby current flows from the source region, through the channel region and to the bit line, and electrons from the current through the channel region are injected onto the floating gate.

A semiconductor device comprises a source region and a drain region formed in a semiconductor substrate, with a channel region of the semiconductor substrate extending between the source region and the drain region, a floating gate disposed over and insulated from, for controlling a conductivity of, a first portion of the channel region, a select gate disposed over and insulated from, for controlling a conductivity of, a second portion of the channel region, a bit line electrically connected to the drain region, a current source, discharge circuitry comprising a voltage source and a first switch having a first open state and a first closed state, a second switch electrically connected between the bit line and the current source, and between the bit line and the discharge circuitry, wherein the second switch has a second closed state that electrically couples the bit line to the current source and the discharge circuitry through the second switch, and wherein the second switch has a second open state that electrically isolates the bit line from the current source and the discharge circuitry, wherein the first switch in the first closed state electrically couples the first switch to the voltage source through the first switch, and wherein the first switch in the first open state electrically isolates the second switch from the voltage source, and control circuitry to, apply a first positive voltage to the select gate, and place the first switch in the first closed state and place the second switch in the second closed state to electrically coupled to the bit line through the first and second switches to the voltage source to decrease a voltage on the bit line.

Other objects and features of the present disclosure will become apparent by a review of the specification, claims and appended figures.

### BRIEF DESCRIPTION OF THE DRAWINGS

FIG. 1 is a cross sectional view of a conventional pair of memory cells.

FIG. 2 is a schematic and layout diagram of a conventional memory cell array of the memory cells of FIG. 1.

FIG. 3 is a side cross sectional view of a conventional pair of memory cells.

FIG. 4 is a schematic and layout diagram of a conventional memory cell array of the memory cells of FIG. 3.

FIG. 5 is a side cross sectional view of a conventional pair of memory cells.

FIG. 6 is a schematic and layout diagram of a conventional memory cell array of the memory cells of FIG. 5.

FIG. 7 is a side cross sectional view of a conventional pair of memory cells.

FIG. 8 is a diagram illustrating components of a semiconductor device.

FIG. 9 is a schematic and layout diagram of a memory cell array of the memory cells of FIG. 1.

FIG. 10 is a timing diagram showing the charging of the bit line.

FIG. 11 is a timing diagram showing the discharging of the bit line.

FIG. 12 is a schematic of a discharge bias voltage generation circuit.

### DETAILED DESCRIPTION OF THE INVENTION

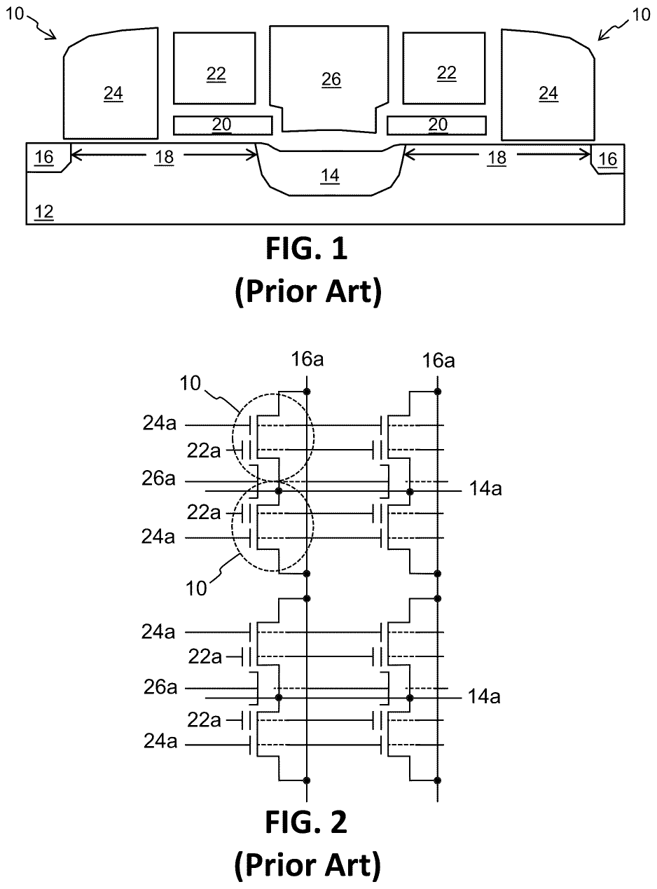

The present examples illustrate semiconductor devices and methods for reducing the time need to program a non-volatile memory cell. The programming methods can be implemented as part of control circuitry 46, which controls the various device elements for a memory array, which can be better understood from the architecture of an example semiconductor device as illustrated in FIG. 8. The semiconductor device includes an array 30 of the memory cells 10, which can be segregated into two separate planes (Plane A 32a and Plane B 32b). The memory cells 10 can be of the type shown in FIG. 1, 3, 5, or 7, arranged in a plurality of rows and columns in the semiconductor substrate 12 as illustrated in FIG. 2, 4 or 6, and thus formed on a single chip. Adjacent to the array 30 of memory cells 10 are an address decoder 34 (e.g., XDEC), source line drivers 36 (e.g., SLDRV), a column decoder 38 (e.g., YMUX), a high voltage row decoder 40 (e.g., HVDEC), a bit line controller 42 (e.g., BLINHCTL), a bit line voltage/current source 48 (e.g., BLDRC), and a charge pump 44 (e.g., CHRGPMP), which are used to decode addresses and supply the various voltages to the various gates and regions of the memory cells 10 during read, program, and erase operations for selected memory cells 10 of the array 30, under the control of the control circuitry 46. Sense amplifier blocks 50 (e.g., SABLK) contain circuitry for measuring the currents on the bit lines during a read operation and supplying current during a program operation. Control circuitry 46 controls the various device elements to implement each operation (program, erase, read) on selected memory cells 10 of the array 30 as described herein. Control circuitry 46 operates the semiconductor device to program, erase and read the selected memory cells 10 of the array 30. As part of these operations, the control circuitry 46 can be provided with access to incoming data which is user data to be programmed to the selected memory cells 10 of the array 30, along with program, erase and read commands provided on the same or different lines. Data read from the array 30 (i.e., from selected memory cells 10 of the array 30) is provided as outgoing data.

The method involves the control circuitry 46 implementing program operations. Thus, control circuitry 46 may be loaded with software, i.e. non-transitory electronically readable instructions, or firmware, or can consist of respective circuits, or any combination thereof, to perform the methods described herein. Control circuitry 46 may be implemented by a microcontroller, dedicated circuitry, a processor, a general purpose processor running firmware or software, or a combination thereof.

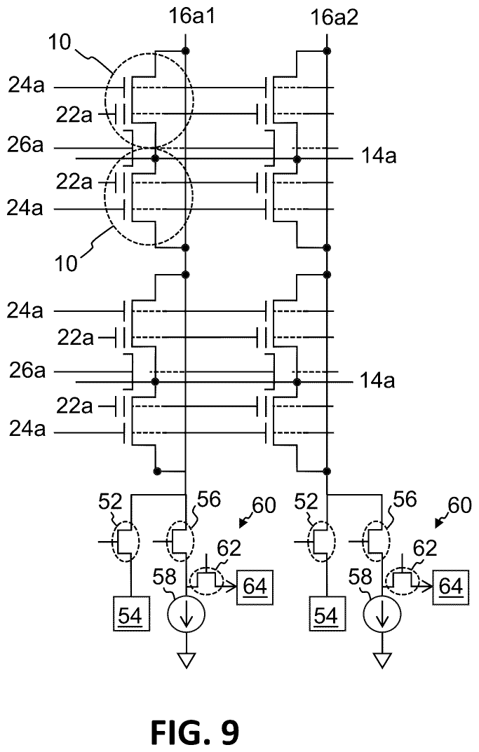

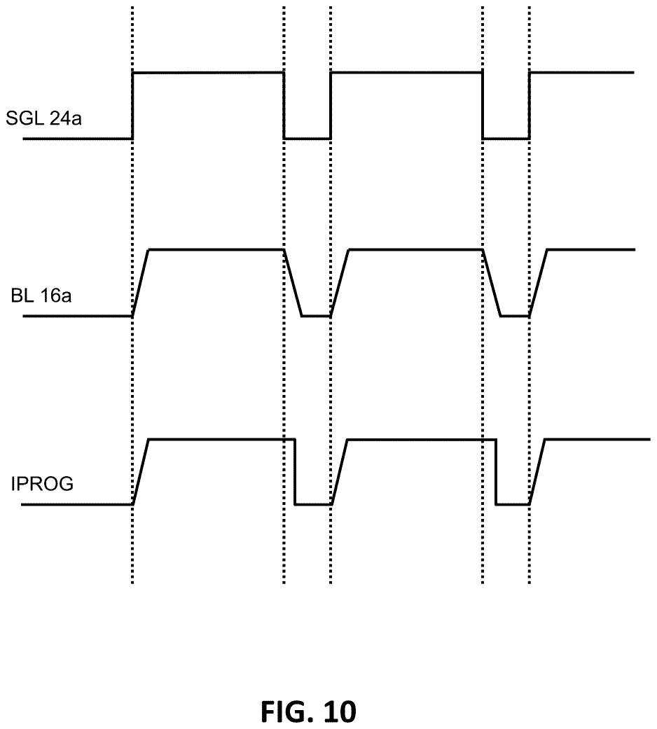

FIG. 9 illustrates additional elements for each of the bit lines of the array of FIG. 2. However, these additional elements equally apply to the arrays of FIGS. 4 and 6. For each bit line 16a, a first switch 52 (e.g., a transistor) having open and closed states for selectively electrically coupling (in the closed state) and electrically isolating (in the open state) the bit line 16a to/from one or more voltage sources 54 that supply voltages such as drain erase voltage Vde, drain read voltage Vdr and a drain inhibit voltage Vdinh. For each bit line 16a, second switch 56 selectively electrically couples (in its closed state) and electrically isolates (in its open state) the bit line 16a to/from a current source 58 that provides program current IPROG.

As used herein, a memory cell 10 targeted for an operation such as program or read can be referred to as the selected memory cell 10. The various lines (bit line 16a, source line 14, control gate line 22a, select gate line 24a and erase gate line 26) electrically connected to the selected memory cell 10 can be referred to as selected bit line 16a, selected source line 14, selected control gate line 22a, selected select gate line 24a and selected erase gate line 26. The remaining lines in the memory array not electrically connected to the selected memory cell may be referred to as unselected lines respectively. The memory cells 10 not targeted for an operation may be referred to as the unselected memory cells. At the time when program voltages are applied to a selected memory cell 10 for programming, the selected bit line 16a (electrically connected to the drain 16 of the selected memory cell 10) may have one of several starting voltages: drain erase voltage Vde (e.g., OV) from a previous erase operation, drain program voltage Vdp (e.g., 0.3V) from a previous program operation, drain read voltage Vdr (e.g., 0.6-2V) from a previous read operation, or a drain inhibit voltage Vdinh (e.g. 1.8-2V) from a previous operation on other memory cells. The drain inhibit voltage Vdinh on the selected bit line 16a can be used to prevent operations on memory cells electrically connected to other bit lines from affecting the memory cells electrically connected to the selected bit line 16a. Therefore, at the beginning of memory cell programming, if the starting voltage on the selected bit line 16a is below the drain program voltage Vdp, then the selected bit line 16a needs to be charged to a higher voltage (i.e., the voltage on the selected bit line 16a is increased) to achieve the drain program voltage Vdp. Conversely, at the beginning of memory cell programming, if the starting voltage on the selected bit line 16a is above the drain program voltage Vdp, then the selected bit line 16a needs to be discharged to a lower voltage (i.e., the voltage on the selected bit line 16a is decreased) to achieve the drain program voltage Vdp.

While the current source 58 can be used to charge and discharge the selected bit line 16a to a higher or a lower voltage (which can take relatively longer than for the other lines given the relatively higher capacitance of the bit lines), it has been discovered by the present inventors that charging the selected bit line 16a to a higher voltage through the selected memory cell 10, and discharging the selected bit line 16a to a lower voltage using a discharge circuitry, is significantly faster than using the current source 58.

When charging the selected bit line 16a from a starting voltage below drain program voltage Vdp, the voltages discussed above for the program operation are applied to the selected memory cell 10, which couples the voltage from the selected source line 14a, through the selected memory cell 10, and to the selected bit line 16a. The rate of bit line charging is a function of the selected memory cell 10, but has been found to be faster than using a current source. The rate of the charging is proportional to the transconductance gm (i.e., gm=∂ID/∂VGS) of the memory cell and capacitance of the bit line. Second switch 56 for the selected bit line 16a can be turned on (closed state) during the charging period, electrically coupling the selected bit line 16a to current source 58. As the voltage on the selected bit line achieves the drain program voltage Vdp, the actual programming occurs on the selected memory cell 10. The control circuitry 46 can control the current source 58 to maintain the voltage on the selected bit line 16a at the drain program voltage Vdp and a desired level of program current IPROG once the drain program voltage Vdp voltage is achieved through bit line charging. It has been discovered by the inventors that the charge time for the selected bit line 16a can be reduced by a factor of 2-20 times depending on the cell capacitance and the array organization (i.e., how many rows of memory cells per bit line). The bit line charging to Vdp level can be enabled by pulsing the voltages on the select gate line 24a or the source line 14a from low to high levels. FIG. 10 illustrates bit line charging and pulsed programming, where charging of the selected bit line 16a coincides with the positive voltage applied to the selected select gate line 24a, and programming of the selected memory cell by the program current IPROG through the channel region 18 of the selected memory cell 10. The control circuitry 46 can utilize sense amplifier block 50 to determine that the starting voltage on selected bit line 16a is below the drain program voltage Vdp and that bit line charging is to be implemented.

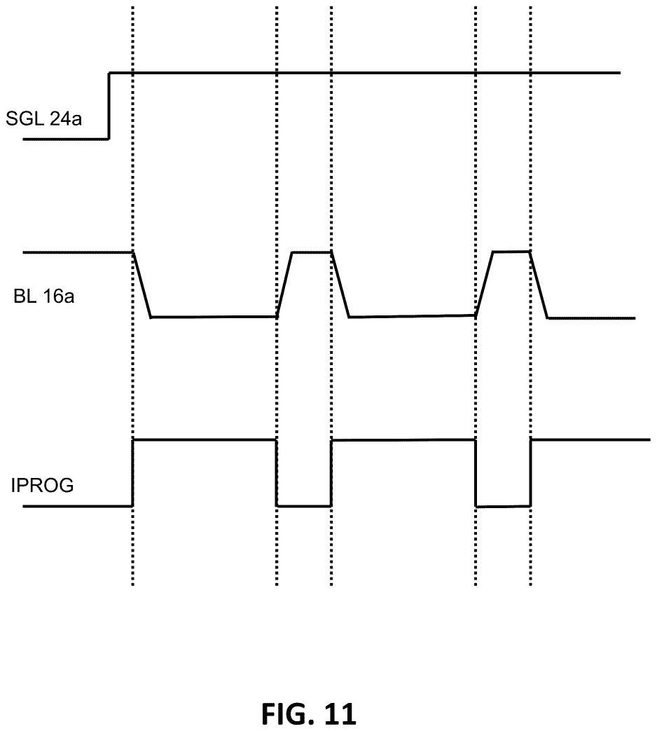

When discharging the selected bit line 16a from a starting voltage above the drain program voltage Vdp, discharge circuitry 60 (as shown in FIG. 9) including a third switch 62 that electrically couples (in the closed state) the output of second switch 56 to node 64 (which is a voltage source at ground or at a trimmable output voltage VBLp_PRE) is used for lowering the voltage on the selected bit line 16a down to approximately equal to drain program voltage Vdp. During bit line discharge, both second and third switches 56, 62 are turned on (in their closed states), electrically coupling the selected bit line 16a to node 64. The discharge circuitry 60 results in the selected bit line 16a settling faster to drain program voltage Vdp relative to just using current source 58. The rate of discharge can be proportional to the discharge current (which can be as high as 100 times the program current) and the bit line capacitance. The control circuitry 46 can control the current source 58 to maintain the voltage on the selected bit line 16a at the drain program voltage Vdp and a desired level of program current IPROG once the drain program voltage Vdp voltage is achieved through bit line discharging. FIG. 11 illustrates bit line discharging and pulsed programming, where discharging of the selected bit line 16a coincides with programming of the selected memory cell by the program current IPROG through the channel region 18 of the selected memory cell 10. The control circuitry 46 can utilize sense amplifier block 50 to determine that the starting voltage on selected bit line 16a is above the drain program voltage Vdp and that bit line discharging is to be implemented.

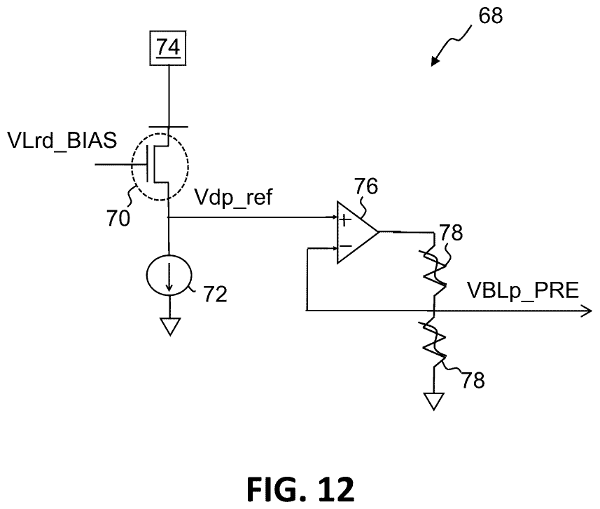

FIG. 12 illustrates a discharge bias voltage generation circuit 68, where a memory cell 70 (which could instead be an NMOS device) is coupled to a current source 72 such that the memory cell's drain is coupled to a high voltage source 74, and its source is coupled to the current source 72. A voltage VLrd_BIAS (similar to the voltage used during the program operation on the select gate lines) is applied to the gate of the memory cell 70, to generate voltage Vdp_ref (which is similar to the voltage Vdp) between the memory cell 70 and current source 72. The voltage Vdp_ref is then buffered by an operational amplifier 76, with an output trimmable by two trimmable resistors 78, to generate a trimmable output voltage VBLp_PRE that serves as the output of the voltage source. This output voltage may be used to discharge the bit line of the memory cells during programming by applying it to node 64 in FIG. 9.

The memory cell 70 (or NMOS device) serves as a reference voltage generator having a first terminal coupled to the source voltage provided by the high voltage source 74 and a second terminal coupled to the current source 72 and a circuit to reduce the source voltage to a reference voltage (e.g., Vdp_ref) that is output at the second terminal. Where the reference voltage generator is a memory cell, then the first terminal is a drain of the memory cell, and the second terminal is a source of the memory cell. Where the reference voltage generator is a NMOS device, the first terminal is a drain of the NMOS device, and the second terminal is a source of the NMOS device. The operational amplifier 76 serves as a buffer having a first input terminal coupled to the second terminal of the reference voltage generator, a buffer circuit to buffer the reference voltage to a buffered output voltage, an output terminal to output the buffered output voltage to the first switch, and a second input terminal coupled to the output terminal. The buffer circuit can include a variable voltage divider circuit (e.g., two trimmable resistors 78) to trim the buffered output voltage.

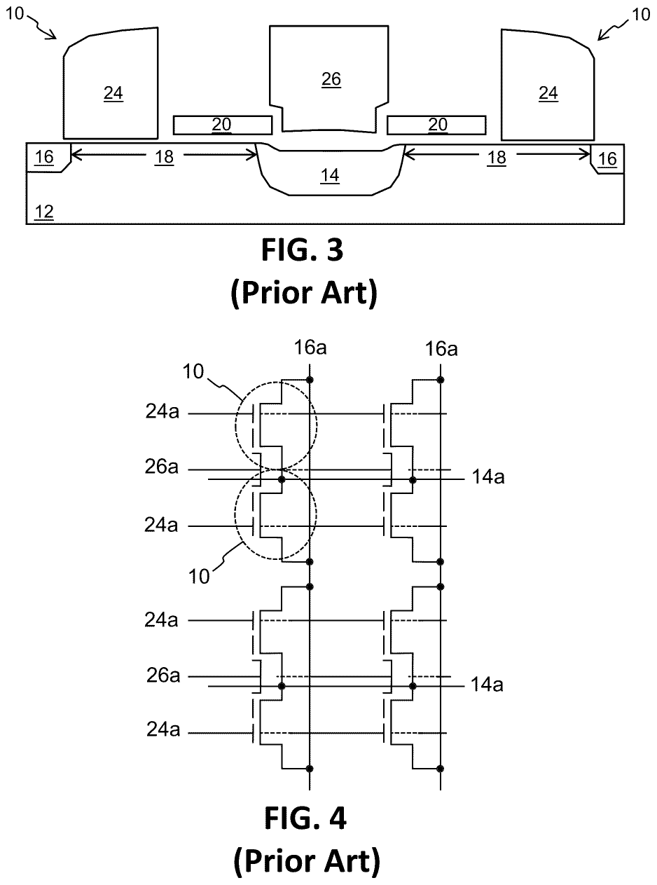

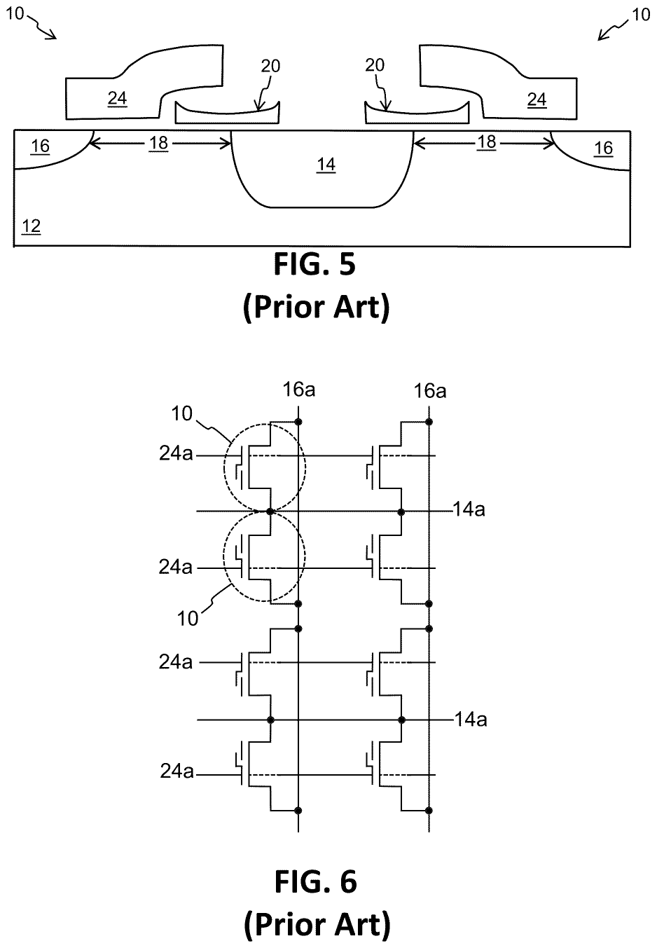

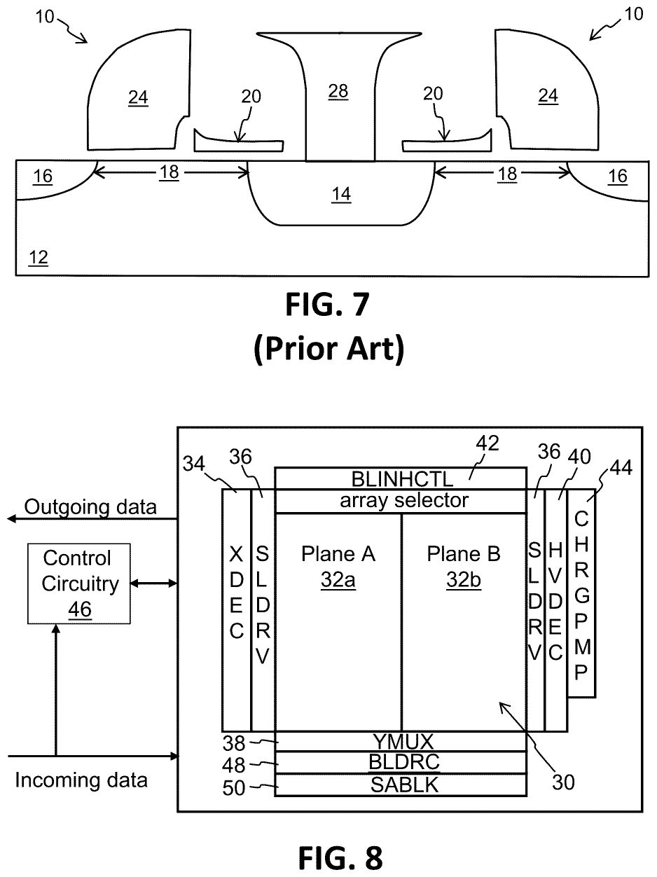

It is to be understood that the present disclosure is not limited to the example(s) described above and illustrated herein, but encompasses any and all variations falling within the scope of any claims. For example, while the above fast program techniques are described with respect to an array of the memory cells of FIG. 1, they are equally applicable to an array of the memory cells of FIG. 3, 5, or 7. References to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order). Single layers of material could be formed as multiple layers of such or similar materials, and vice versa. The terms “forming” and “formed” as used herein shall include material deposition, material growth, or any other technique in providing the material as disclosed or claimed. The claims are comprising claims unless otherwise stated, and therefore “each” of a plurality of elements having a limitation does not preclude the inclusion of additional such elements lacking the limitation unless otherwise specifically claimed. It should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry.

What is claimed is:

1. A method of operating a semiconductor device, wherein the semiconductor device comprises:
a source region and a drain region formed in a semiconductor substrate, with a channel region of the semiconductor substrate extending between the source region and the drain region;
a floating gate disposed over and insulated from, for controlling a conductivity of, a first portion of the channel region;
a select gate disposed over and insulated from, for controlling a conductivity of, a second portion of the channel region;
a bit line electrically connected to the drain region; and
a current source;
the method comprising:
applying a first positive voltage to the select gate;
applying a second positive voltage to the source region;
wherein current flows from the source region, through the channel region and to the bit line to increase a voltage on the bit line; and
after the increase of the voltage on the bit line, maintaining a drain program voltage on the bit line whereby electrons from the current through the channel region are injected onto the floating gate.

2. The method of claim 1, wherein the second positive voltage is greater than the first positive voltage.

3. The method of claim 1, wherein:
the semiconductor device comprises a switch electrically connected between the bit line and the current source, wherein the switch has a closed state that electrically couples the bit line to the current source through the switch, and wherein the switch has an open state that electrically isolates the bit line from the current source; and
the method comprises placing the switch in the closed state before the increase of the voltage on the bit line.

4. A semiconductor device, comprising:
a source region and a drain region formed in a semiconductor substrate, with a channel region of the semiconductor substrate extending between the source region and the drain region;
a floating gate disposed over and insulated from, for controlling a conductivity of, a first portion of the channel region;
a select gate disposed over and insulated from, for controlling a conductivity of, a second portion of the channel region;
a bit line electrically connected to the drain region;
a current source;
a switch electrically connected between the bit line and the current source, wherein the switch has a closed state that electrically couples the bit line to the current source through the switch, and wherein the switch has an open state that electrically isolates the bit line from the current source; and
control circuitry to:
place the switch in the closed state, and
apply a first positive voltage to the select gate and a second positive voltage to the source region, to enable current from the source region, through the channel region and to the bit line to increase a voltage on the bit line.

5. The semiconductor device of claim 4, wherein the second positive voltage is greater than the first positive voltage.

6. The semiconductor device of claim 4, wherein the control circuitry to, after the increase of the voltage on the bit line, maintain a drain program voltage on the bit line to enable injection of electrons onto the floating gate from the current through the channel region.

7. A method of operating a semiconductor device, wherein the semiconductor device comprises:
a source region and a drain region formed in a semiconductor substrate, with a channel region of the semiconductor substrate extending between the source region and the drain region;
a floating gate disposed over and insulated from, for controlling a conductivity of, a first portion of the channel region;
a select gate disposed over and insulated from, for controlling a conductivity of, a second portion of the channel region;
a bit line electrically connected to the drain region;
a current source; and
discharge circuitry comprising a voltage source;
the method comprising:
applying a first positive voltage to the select gate;
applying a second positive voltage to the source region;
electrically coupling the voltage source to the bit line to decrease a voltage on the bit line; and
after the decrease of the voltage on the bit line, maintaining a drain program voltage on the bit line whereby current flows from the source region, through the channel region and to the bit line, and electrons from the current through the channel region are injected onto the floating gate.

8. The method of claim 7, wherein:
the discharge circuitry comprises a first switch having a first open state and a first closed state;
the semiconductor device comprises a second switch electrically connected between the bit line and the current source, and between the bit line and the discharge circuitry, wherein the second switch has a second closed state that electrically couples the bit line to the current source and the discharge circuitry through the second switch, and wherein the second switch has a second open state that electrically isolates the bit line from the current source and the discharge circuitry;
the first switch in the first closed state electrically couples the first switch to the voltage source through the first switch, and wherein the first switch in the first open state electrically isolates the second switch from the voltage source; and
the method comprises, before the decrease of the voltage on the bit line:
placing the first switch in the first closed state; and
placing the second switch in the second closed state.

9. The method of claim 8, wherein the voltage source is ground.

10. The method of claim 8, wherein the voltage source comprises:
a reference voltage generator comprising a first terminal coupled to a source voltage, a second terminal coupled to a current source, and a circuit to reduce the source voltage to a reference voltage and output the reference voltage at the second terminal; and
a buffer comprising a first input terminal coupled to the second terminal of the reference voltage generator, a buffer circuit to buffer the reference voltage to a buffered output voltage, an output terminal to output the buffered output voltage to the first switch, and a second input terminal coupled to the output terminal.

11. The method of claim 10, wherein the reference voltage generator is a memory cell, the first terminal is a drain of the memory cell, and the second terminal is a source of the memory cell.

12. The method of claim 10, the reference voltage generator is a NMOS device, the first terminal is a drain of the NMOS device, and the second terminal is a source of the NMOS device.

13. The method of claim 10, wherein the buffer circuit comprises an operational amplifier.

14. The method of claim 10, wherein the buffer circuit comprises a variable voltage divider circuit to trim the buffered output voltage.

15. A semiconductor device, comprising:
a source region and a drain region formed in a semiconductor substrate, with a channel region of the semiconductor substrate extending between the source region and the drain region;
a floating gate disposed over and insulated from, for controlling a conductivity of, a first portion of the channel region;
a select gate disposed over and insulated from, for controlling a conductivity of, a second portion of the channel region;
a bit line electrically connected to the drain region;
a current source;
discharge circuitry comprising a voltage source and a first switch having a first open state and a first closed state;
a second switch electrically connected between the bit line and the current source, and between the bit line and the discharge circuitry, wherein the second switch has a second closed state that electrically couples the bit line to the current source and the discharge circuitry through the second switch, and wherein the second switch has a second open state that electrically isolates the bit line from the current source and the discharge circuitry;
wherein the first switch in the first closed state electrically couples the first switch to the voltage source through the first switch, and wherein the first switch in the first open state electrically isolates the second switch from the voltage source; and
control circuitry to:
apply a first positive voltage to the select gate; and
place the first switch in the first closed state and place the second switch in the second closed state to electrically coupled to the bit line through the first and second switches to the voltage source to decrease a voltage on the bit line.

16. The semiconductor device of claim 15, wherein the control circuitry to:
apply a second positive voltage to the source region to enable current to flow from the source region, through the channel region and to the bit line.

17. The semiconductor device of claim 16, wherein the control circuitry to, after the decrease of the voltage on the bit line, maintain a drain program voltage on the bit line to enable injection of electrons onto the floating gate from the current through the channel region.

18. The semiconductor device of claim 15, wherein the voltage source is ground.

19. The semiconductor device of claim 15, wherein the voltage source comprises:
a reference voltage generator comprising a first terminal coupled to a source voltage, a second terminal coupled to a current source, and a circuit to reduce the source voltage to a reference voltage and output the reference voltage at the second terminal; and
a buffer comprising a first input terminal coupled to the second terminal of the reference voltage generator, a buffer circuit to buffer the reference voltage to a buffered output voltage, an output terminal to output the buffered output voltage to the first switch, and a second input terminal coupled to the output terminal.

20. The semiconductor device of claim 19, wherein the reference voltage generator is a memory cell, the first terminal is a drain of the memory cell, and the second terminal is a source of the memory cell.

21. The semiconductor device of claim 19, the reference voltage generator is a NMOS device, the first terminal is a drain of the NMOS device, and the second terminal is a source of the NMOS device.

22. The semiconductor device of claim 19, wherein the buffer circuit comprises an operational amplifier.

23. The semiconductor device of claim 19, wherein the buffer circuit comprises a variable voltage divider circuit to trim the buffered output voltage.
